(19) United States
(12) Patent Application Publication
(10) Pub. No.: US 2020/0244219 A1
(43) Pub. Date: Jul. 30, 2020

(54) HIGH-SPEED OSCILLATION CIRCUIT WITH LOW-TEMPERATURE COEFFICIENT

(71) Applicant: Global Mixed-mode Technology Inc., Hsin-Chu (TW)

(72) Inventors: Guang-Nan Tzeng, Hsinchu City (TW); Chung-Wei Lin, Hsinchu County (TW)

(21) Appl. No.: 16/261,585

(22) Filed: Jan. 30, 2019

(51) Int. Cl. H03B 5/04

(52) U.S. Cl. CPC H03B 5/04

(57) ABSTRACT

An oscillation circuit that is robust and more accurate is provided. The oscillation circuit includes a reference voltage generator, a voltage-to-current converter, a capacitor, a pull-low circuit, and a single-ended input comparator. The reference voltage generator is used for generating a voltage signal. The voltage-to-current converter receives the voltage signal for generating a reference current. The capacitor is coupled to the voltage-to-current converter for generating a ramp signal. The single-ended input comparator receives the ramp signal for generating a clock signal. The pull-low circuit receives the clock signal for pulling the ramp signal low.

### BACKGROUND OF THE INVENTION

### 1. Field of the Invention

The present invention relates to an oscillation circuit, and more particularly, to a high-speed oscillation circuit with low-temperature coefficient.

### 2. Description of the Prior Art

One of the problems often associated with the use of an oscillation circuit lies in the fact that such oscillation circuit is often unstable, with its oscillating period being variable as the ambient temperature to which it is exposed changes. A high-speed oscillation circuit with low-temperature coefficient is particularly useful as a temperature independent clock to generate timing signals for use in memory circuits nowadays.

Thus, what is needed is the oscillation circuit with low-temperature coefficient that is robust and more accurate.

### SUMMARY OF THE INVENTION

According to the present invention, an oscillation circuit comprises a reference voltage generator, a voltage-to-current converter, a capacitor, a pull-low circuit, and a single-ended input comparator. The reference voltage generator is used for generating a voltage signal. The voltage-to-current converter receives the voltage signal for generating a reference current. The capacitor is coupled to the voltage-to-current converter for generating a ramp signal. The single-ended input comparator receives the ramp signal for generating a clock signal. The pull-low circuit receives the clock signal for pulling the ramp signal low.

The reference voltage generator is used for generating a reference voltage. The single-ended input comparator has a transient voltage when forming an inverter structure. Due to the similar circuit structure between the reference voltage generator and the single-ended input comparator, the transient voltage is equal to the reference voltage under a proper design consideration. A high-speed oscillation circuit with low-temperature coefficient can be obtained as a result.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above-mentioned and other objects, features, and advantages of the present invention will become apparent with reference to the following descriptions and accompanying drawings, wherein:

FIG. 1 is a circuit diagram showing an oscillation circuit according to one embodiment of the present invention;

FIG. 2 is a circuit showing a reference voltage generator according to one embodiment of the present invention;

FIG. 3 is a circuit showing a voltage-to-current converter according to one embodiment of the present invention; and

FIG. 4 is a circuit showing a single-ended input comparator according to one embodiment of the present invention.

### DETAILED DESCRIPTION

Preferred embodiments according to the present invention will be described in detail with reference to the drawings.

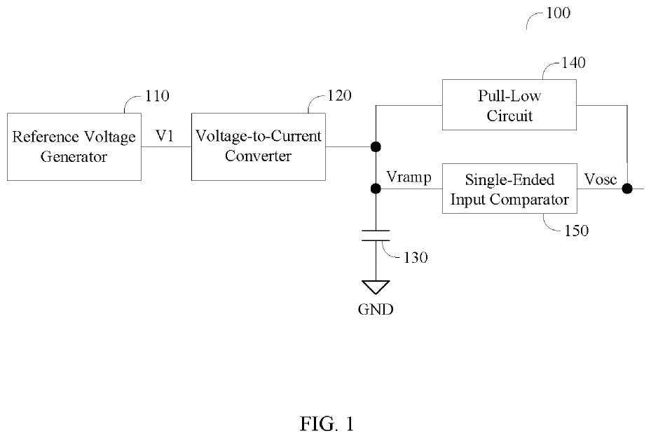

FIG. 1 is a circuit diagram showing an oscillation circuit 100 according to the present invention. The oscillation circuit 100 comprises a reference voltage generator 110, a voltage-to-current converter 120, a capacitor 130, a pull-low circuit 140, and a single-ended input comparator 150. The reference voltage generator 110 is used for generating a voltage signal V1. The voltage-to-current converter 120 receives the voltage signal V1 for generating a reference current Iref. The capacitor 130 is coupled to the voltage-to-current converter 120 for generating a ramp signal Vramp. The single-ended input comparator 150 receives the ramp signal Vramp for generating a clock signal Vosc. The pull-low circuit 140 receives the clock signal Vosc for pulling the ramp signal Vramp low.

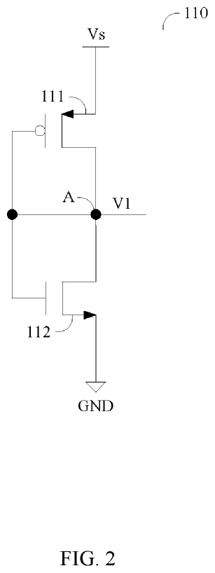

FIG. 2 is the circuit showing the reference voltage generator 110 according to one embodiment of the present invention. The reference voltage generator 110 comprises a transistor 111 and a transistor 112 for generating a voltage signal V1. The transistor 111 has a channel width W1 and a channel length L1. The transistor 112 has a channel width W2 and a channel length L2. The transistor 111 has a source coupled to a voltage source Vs and a drain coupled to its own gate. The transistor 112 has a source coupled to the ground GND and a drain coupled to its own gate. Moreover, the gate of the transistor 111 is coupled to the gate of the transistor 112 and the drain of the transistor 111 (i.e. node A) is coupled to the drain of the transistor 112, so as to form a resistive voltage divider. Under normal operation, the voltage created by the voltage source Vs should be greater than two threshold voltages for generating a reference voltage Vref at the node A.

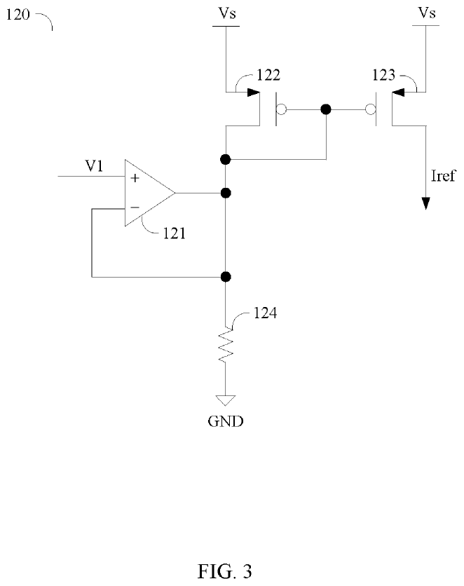

FIG. 3 is the circuit showing the voltage-to-current converter 120 according to one embodiment of the present invention. The voltage-to-current converter 120 comprises an operational amplifier 121, a transistor 122, a transistor 123, and a resistor 124. The operational amplifier 121 has a non-inverting input terminal coupled to the voltage signal V1, an inverting input terminal coupled to the resistor 124, and an output terminal coupled to the inverting input terminal of the operational amplifier 121. The resistor 124 is coupled to the ground GND and has a resistance R. The transistor 122 has a source coupled to the voltage source Vs, a drain coupled to the output terminal of the operational amplifier 121, and a gate coupled to its own drain. The transistor 123 has a source coupled to the voltage source Vs, a gate coupled to the gate of the transistor 122, and a drain for generating a reference current Iref. Accordingly, the reference current Iref is equal to Vref/R when the transistor 122 is identical to the transistor 123 in transistor size.

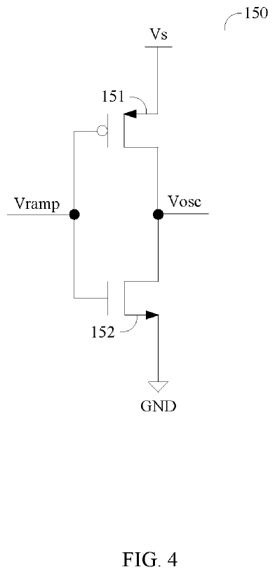

FIG. 4 is the circuit showing the single-ended input comparator 150 according to the present invention. The single-ended input comparator 150 comprises a transistor 151 and a transistor 152 with a similar circuit structure when compared to the reference voltage generator 110. The transistor 151 has a channel width W3 and a channel length L3. The transistor 152 has a channel width W4 and a channel length L4. The transistor 151 has a source coupled to the voltage source Vs, a gate coupled to the capacitor 130, and a drain. The transistor 152 has a source coupled to the ground GND, a gate coupled to the capacitor 130, and a drain. Moreover, the drain of the transistor 151 is coupled to the drain of the transistor 152 for generating the clock signal Vosc. The clock signal Vosc has an oscillating period T. The single-ended input comparator 150 has a transient voltage Vcomp when forming an inverter structure. Since the single-ended input comparator 150 is a one-stage circuit structure, a high-speed operation can be achieved and the oscillating period T can be more accurate.

Due to the similar circuit structure between the reference voltage generator 110 and the single-ended input comparator 150, the transient voltage Vcomp can be related to the reference voltage Vref through a proper design consideration. As long as the ratio of the channel width W3 to the channel length L3 is N times as large as the ratio of the channel width W1 to the channel length L1 and the ratio of the channel width W4 to the channel length L4 is N times as large as the ratio of the channel width W2 to the channel length L2, the transient voltage Vcomp will be equal to the reference voltage Vref. N is a positive number according to one embodiment of the present invention.

In operation, the oscillating period T is equal to the charging time of the capacitor 130. The capacitor 130 has a capacitance C. Thus, a formula can be expressed as Iref*T=C*Vcomp for determining the oscillating period T. Since the reference current Iref is equal to Vref/R and the transient voltage Vcomp is equal to the reference voltage Vref, the oscillating period T will be equal to R*C. In general, the capacitance C is very insensitive to the temperature. A high-speed oscillation circuit with low-temperature coefficient can be obtained as long as the resistor 124 with low-temperature coefficient is selected. The oscillating period T is substantially independent of the temperature as a result.

While the present invention has been described by the preferred embodiment, it is to be understood that the invention is not limited to the disclosed embodiment. On the contrary, it is intended to cover various modifications. Therefore, the scope of the appended claims should be accorded the broadest interpretation so as to encompass all such modifications.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An oscillation circuit comprising:
a reference voltage generator configured to generate a voltage signal;
a voltage-to-current converter configured to receive the voltage signal;
a capacitor coupled to the voltage-to-current converter for generating a ramp signal;
a single-ended input comparator configured to receive the ramp signal for generating a clock signal; and
a pull-low circuit configured to receive the clock signal for pulling the ramp signal low.

2. The oscillation circuit of claim 1, wherein the reference voltage generator comprises:
a first transistor having a source coupled to a voltage source, a gate, and a drain coupled to the gate of the first transistor; and
a second transistor having a source coupled to ground, a gate, and a drain coupled to the gate of the second transistor, wherein:
the gate of the first transistor is coupled to the gate of the second transistor, and the drain of the first transistor is coupled to the drain of the second transistor.

3. The oscillation circuit of claim 2, wherein the single-ended input comparator comprises:
a third transistor having a source coupled to the voltage source, a gate coupled to the capacitor, and a drain; and
a fourth transistor having a source coupled to the ground, a gate coupled to the capacitor, and a drain, wherein:
the drain of the third transistor is coupled to the drain of the fourth transistor for generating the clock signal.

4. The oscillation circuit of claim 3, wherein:
the first transistor has a first channel width and a first channel length;
the second transistor has a second channel width and a second channel length;
the third transistor has a third channel width and a third channel length;
the fourth transistor has a fourth channel width and a fourth channel length; and
the ratio of the third channel width to the third channel length is N times as large as the ratio of the first channel width to the first channel length and the ratio of the fourth channel width to the fourth channel length is N times as large as the ratio of the second channel width to the second channel length, where N is a positive number.

5. The oscillation circuit of claim 2, wherein the voltage-to-current converter comprises:
an operational amplifier having a non-inverting input terminal coupled to the voltage signal, an inverting input terminal, and an output terminal coupled to the inverting input terminal of the operational amplifier;
a resistor coupled to the inverting input terminal of the operational amplifier;
a fifth transistor having a source coupled to the voltage source, a drain coupled to the output terminal of the operational amplifier, and a gate coupled to the drain of the fifth transistor; and
a sixth transistor having a source coupled to the voltage source, a gate coupled to the gate of the fifth transistor, and a drain for generating a reference current.

6. The oscillation circuit of claim 5, wherein the fifth transistor is identical to the sixth transistor in transistor size.

7. The oscillation circuit of claim 1, wherein the clock signal has an oscillating period and the oscillating period is substantially temperature-independent.
